(19) United States
(12) Patent Application Publication
(10) Pub. No.: US 2025/0267939 A1
(43) Pub. Date: Aug. 21, 2025

(54) SILICON-ON-INSULATOR TRANSVERSE DEVICE AND MANUFACTURING METHOD THEREFOR

(71) Applicant: CSMC TECHNOLOGIES FAB2 CO., LTD., Wuxi, Jiangsu (CN)

(72) Inventors: Teng LIU, Wuxi (CN); Wentong ZHANG, Wuxi (CN); Nailong HE, Wuxi (CN); Zhili ZHANG, Wuxi (CN); Hua SONG, Wuxi (CN)

(21) Appl. No.: 18/858,145

(22) PCT Filed: Mar. 15, 2023
(86) PCT No.: PCT/CN2023/081575

§ 371 Date: Oct. 18, 2024

(30) Foreign Application Priority Data
Apr. 21, 2022 (CN) 202210419589.3

(51) Int. Cl. H10D 86/00; H10D 1/00; H10D 1/66; H10D 30/01; H10D 30/65; H10D 62/10; H10D 86/80

(52) U.S. Cl. CPC H10D 86/201; H10D 1/047; H10D 1/665; H10D 30/0281; H10D 30/657; H10D 62/103; H10D 62/126; H10D 86/80

(57) ABSTRACT

The present application relates to a silicon-on-insulator transverse device and a manufacturing method therefor. The device comprises: a substrate; a buried dielectric layer provided on the substrate; a drift region provided on the buried dielectric layer, a vertical conductive structure extending downwards from the drift region to the buried dielectric layer; a low-K dielectric provided in the buried dielectric layer and surrounding the bottom of the vertical conductive structure; and a dielectric layer provided on a side surface of the vertical conductive structure and located between the vertical conductive structure and the drift region and above the low-K dielectric.

### CROSS-REFERENCE TO RELATED APPLICATIONS

This application claims priority to Chinese Patent Application No. 2022104195893, entitled “SILICON-ON-INSULATOR TRANSVERSE DEVICE AND MANUFACTURING METHOD THEREFOR”, filed with the China Patent Office on Apr. 21, 2022, the entire content of which is incorporated herein by reference.

### TECHNICAL FIELD

The present disclosure relates to the field of semiconductor manufacturing, and in particular, to a silicon-on-insulator (SOI) transverse device, and further to a manufacturing method for a SOI transverse device.

### BACKGROUND

Due to a unique structure, a silicon-on-insulator (SOI) overcomes the shortcomings of bulk silicon materials and gives full play to potential of a silicon integrated circuit technology, which, compared with a bulk silicon technology, has advantages of a high speed, low power consumption, high integration, and easy isolation.

In the research of SOI high-voltage transverse devices, the industry attempts to use junction terminal voltage withstanding technologies such as reduced surface field (RESURF) structures, field plate structures, and transverse gradient doping in conventional bulk silicon devices to solve the voltage withstanding problem of the devices. However, since a substrate of a SOI device is isolated by a dielectric layer, a longitudinal RESURF effect at the bottom is weakened, and a voltage withstanding effect is not good in the field of high-voltage devices.

### SUMMARY

According to exemplary embodiments of the present disclosure, a SOI transverse device and a manufacturing method therefor are provided.

A SOI transverse device, including: a substrate; a buried dielectric layer provided on the substrate: a drift region provided on the buried dielectric layer; a vertical conductive structure extending downwards from the drift region to the buried dielectric layer: a low-K dielectric provided in the buried dielectric layer and surrounding the bottom of the vertical conductive structure, a dielectric constant of the low-K dielectric being less than a dielectric constant of the buried dielectric layer; and a dielectric layer provided on a side surface of the vertical conductive structure and located between the vertical conductive structure and the drift region and above the low-K dielectric.

According to the above SOI transverse device, the vertical conductive structure, the dielectric layer, and the drift region form a capacitor effect similar to the capacitor effect formed by a conductive material, a dielectric material, and a semiconductor, which can assist in depletion of the drift region and can also make equipotential lines at the bottom of the drift region to be located at a structure below the vertical conductive structure when the device reversely cuts off. Since the low-K dielectric is located at a portion with highest density of the equipotential lines, when the transverse device is in a reverse cutoff region, an electric field in the dielectric can be greatly enhanced, thereby increasing a breakdown voltage.

In an embodiment, the transverse device is a laterally diffused metal-oxide-semiconductor field-effect transistor (LDMOSFET), and the transverse device further includes: a source region: a drain region; and a gate provided above a region between the source region and the drain region. The vertical conductive structure is located between the gate and the drain region. The source region, the drain region, and the drift region have a first conductivity type.

In an embodiment, the SOI transverse device further includes: a field oxide layer provided on the drift region; and a substrate leading-out region having a second conductivity type and provided on a side of the source region facing away from the gate. The gate extends from an edge of the source region to the field oxide layer.

In an embodiment, the SOI transverse device further includes a first-conductivity-type well region and a second-conductivity-type well region. The drain region is located in the first-conductivity-type well region, the source region and the substrate leading-out region are located in the second-conductivity-type well region. The vertical conductive structure is located between the first-conductivity-type well region and the second-conductivity-type well region.

In an embodiment, the drift region is provided with at least one column of vertical conductive structures, each column including at least two vertical conductive structures spaced apart. An angle between a column direction and a length direction of a conductive channel is greater than 0 degrees on a horizontal plane. The SOI transverse device further includes at least one conductive equipotential structure, each conductive equipotential structure being electrically connected to one column of vertical conductive structures.

In an embodiment, the drift region is provided with at least one column of vertical conductive structures, each column including at least two vertical conductive structures spaced apart. A column direction is a width direction of a conductive channel. The SOI transverse device further includes at least one conductive equipotential strip provided on the field oxide layer, each conductive equipotential strip extending downwards through the field oxide layer by means of a conductive material and being electrically connected to one column of vertical conductive structures.

In an embodiment, each conductive equipotential strip extends in the width direction of the conductive channel.

In an embodiment, each conductive equipotential strip is made of a material including metal or alloy.

In an embodiment, the vertical conductive structure is made of a material including polysilicon.

In an embodiment, the low-K dielectric is made of a material including silicon oxyfluoride.

In an embodiment, the dielectric layer is made of silicon oxide.

In an embodiment, the buried dielectric layer is a buried oxide layer.

In an embodiment, the bottom of the low-K dielectric is in direct contact with the substrate.

In an embodiment, the top of the low-K dielectric is flush with the top of the buried dielectric layer.

In an embodiment, the top of the low-K dielectric is higher than the top of the buried dielectric layer.

In an embodiment, the first conductivity type is N-type, and the second conductivity type is P-type.

A manufacturing method for a SOI transverse device, including: providing a SOI wafer, the SOI wafer including a substrate, a buried dielectric layer on the substrate, and a drift region on the buried dielectric layer; forming a trench in the drift region and the buried dielectric layer by etching down the drift region, etching through the drift region, and then continuously etching the buried dielectric layer; filling the bottom of the trench with a low-K dielectric: forming a dielectric layer on a sidewall of the trench; and forming a vertical conductive structure by filling the trench having the dielectric layer formed on the sidewall with a conductive material. A dielectric constant of the low-K dielectric is less than a dielectric constant of the buried dielectric layer.

According to the above manufacturing method for a SOI transverse device, the vertical conductive structure, the dielectric layer, and the drift region form a capacitor effect similar to the capacitor effect formed by a conductive material, a dielectric material, and a semiconductor, which can assist in depletion of the drift region and can also make equipotential lines at the bottom of the drift region presto be located at a structure below the vertical conductive structure when the device reversely cuts off. Since the low-K dielectric is located at a portion with highest density of the equipotential lines, when the transverse device is in a reverse cutoff region, an electric field in the dielectric can be greatly enhanced, thereby increasing a breakdown voltage.

In an embodiment, the etching the buried dielectric layer includes etching through the buried dielectric layer to the substrate.

In an embodiment, the manufacturing method further includes, subsequent to the filling the bottom of the trench with the low-K dielectric and prior to the forming the dielectric layer on the sidewall of the trench: etching back the low-K dielectric.

In an embodiment, the forming the vertical conductive structure by filling the trench having the dielectric layer formed on the sidewall with the conductive material further includes causing the low-K dielectric to surround the bottom of the vertical conductive structure.

In an embodiment, the manufacturing method further includes, subsequent to the forming the vertical conductive structure by filling the trench having the dielectric layer formed on the sidewall with the conductive material: forming a first-conductivity-type well region and a second-conductivity-type well region: forming a field oxide layer on the drift region: forming a gate: forming a source region and a substrate leading-out region in the second-conductivity-type well region and forming a drain region in the first-conductivity-type well region; and forming conductive equipotential strips electrically connecting a plurality of vertical conductive structures.

### BRIEF DESCRIPTION OF THE DRAWINGS

In order to better describe and illustrate embodiments and/or examples of those contents disclosed herein, reference may be made to one or more accompanying drawings. Additional details or examples used to describe the accompanying drawings should not be considered as limitations on the scope of any of the disclosed contents, the presently described embodiments and/or examples, and the presently understood best mode of these contents.

FIG. 1 is a perspective view of a SOI transverse device according to an embodiment.

FIG. 2 is a schematic cross-sectional view of the SOI transverse device shown in FIG. 1.

FIG. 3a and FIG. 3b are respectively schematic views of distribution of vertical conductive structures on a cross section of a drift region in two embodiments.

FIG. 4 is a flowchart of a manufacturing method for a SOI transverse device according to an embodiment.

FIG. 5 is a flowchart of the manufacturing method for a SOI transverse device after step S450 in FIG. 4 according to an embodiment.

### DETAILED DESCRIPTION

For easy understanding of the present disclosure, a more comprehensive description of the present disclosure is given below with reference to the accompanying drawings. Preferred embodiments of the present disclosure are illustrated in the accompanying drawings. However, the present disclosure may be implemented in many different forms and is not limited to the embodiments described herein. Rather, these embodiments are provided to make the contents disclosed in the present disclosure more thoroughly and comprehensive.

Unless otherwise defined, all technical and scientific terms used herein have the same meaning as commonly understood by those of ordinary skill in the art to which the present disclosure belongs. The terms used in the specification of the present disclosure are intended only to describe particular embodiments and are not intended to limit the present disclosure. The term “and/or” used herein includes any and all combinations of one or more of the associated listed items.

It should be understood that when an element or layer is referred to as being “on”, “adjacent to”, “connected to”, or “coupled to” another element or layer, the element or layer may be directly on, adjacent to, connected to, or coupled to the another element or layer, or an intervening element or layer may be provided therebetween. On the contrary, when an element is referred to as being “directly on”, “directly adjacent to”, “directly connected to”, or “directly coupled to” another element or layer, no intervening element or layer may be provided therebetween. It should be understood that although terms such as first, second, and third may be used to describe various elements, components, regions, layers, and/or portions, the elements, components, regions, layers, and/or portions may not be limited to such terms. Such terms are used only to distinguish one element, component, region, layer, or portion from another element, component, region, layer, or portion. Thus, without departing from the teaching of the present disclosure, a first element, component, region, layer, or portion may be referred to as a second element, component, region, layer, or portion.

Spatial relationship terms such as “under”, “underneath”, “below”, “beneath”, “over”, and “above” may be used for illustrative purposes to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is flipped, an element or a feature described as “below”, “underneath” or “under” another element or feature may be oriented as “on” the another element or feature. Thus, the exemplary terms “below” and “under” may include two orientations of above and below. In addition, the device may be additionally orientated (e.g., rotated by 90-degree or orientated in other ways), and thus spatial descriptors used herein may be interpreted accordingly.

The terms used herein are for the purpose of describing particular embodiments only and are not intended to limit the present disclosure. In use, the singular forms of “a/an”, “one”, and “the” may also include plural forms, unless otherwise clearly specified in the context. It should be further understood that the terms “composed of” and/or “including/comprising” when used in this specification specify the presence of the features, integers, steps, operations, elements, and/or components, but may not exclude the presence or addition of one or more of other features, integers, steps, operations, elements, components, and/or groups. When used herein, the term “and/or” may include any and all combinations of associated listed items.

Embodiments of the present disclosure are described herein with reference to cross-sectional views that are schematic views of ideal embodiments (and intermediate structures) of the present disclosure, so that variants in the shapes shown due to, for example, manufacturing techniques and/or tolerances can be expected. Therefore, embodiments of present disclosure should not be limited to the specific shapes of the regions shown herein, and includes shape deviations due to, for example, manufacturing techniques. For example, an implantation region shown as a rectangle generally has rounded or curved features and/or an injected concentration gradient at its edges, rather than a binary change from the implantation region to a non-implantation region. Similarly, a buried region formed by implantation may result in some implantations in the region between the buried region and the surface through which the implantation takes place. Therefore, the regions shown in the figures are schematic in nature, their shapes do not represent the actual shape of the region of the device, and do not limit the scope of the application.

The vocabulary in the semiconductor field used herein is a technical vocabulary commonly used by those skilled in the art. For example, for P-type and N-type impurities, in order to distinguish doping concentration, it is simple to use P+ type to represent P type of heavy doping concentration, use P type to represent P type of medium doping concentration, use P-type to represent P type of light doping concentration, use N+ type to represent N type of the heavy doping concentration, use N type to represent N type of the medium doping concentration, and use N-type to represent N type of the light doping concentration.

A substrate depletion effect in bulk silicon is replaced by a form similar to a metal oxide semiconductor (MOS) capacitor in a silicon-on-insulator (SOI) structure (longitudinally, a substrate, a buried oxide layer, and an active region form a MOS capacitor structure). At a low voltage, an inversion charge formed at an interface between the buried oxide layer and the drift region forms part of an electric field of a source charge. At a high voltage, a source PN junction gradually expands, a reverse-biased space charge region extends to the buried oxide layer, and the inversion charge is extracted. According to Gauss's theorem, a relationship between an electric field and an interface charge of two dielectrics (the silicon layer drift region and the buried oxide layer) is expressed as:

E_{IεI}=E_{siεsi}+Q_{SI}

where E_{I} denotes electric field intensity of a silicon interface, a denotes a dielectric constant of silicon, Eₛᵢ denotes electric field intensity of the buried oxide layer, εₛᵢ denotes a dielectric constant of the buried oxide layer, and Q_{SI} denotes a product of charge density at the interface between the drift region and the buried oxide layer and q. As can be seen from the interface Gauss's theorem, the use of the low-K dielectric can enhance the electric field of the dielectric. The present disclosure proposes a new high-voltage SOI transverse device including an etched deep trench with the bottom of the deep trench filled with the low-K dielectric. The deep trench goes deep into the buried oxide layer, and equipotential lines are concentrated at the bottom of the deep trench. In addition, the bottom of the deep trench is filled with the low-K dielectric, so that without reducing ON-resistance, the electric field can be greatly enhanced, thereby increasing a breakdown voltage. Contradiction between reducing the ON-resistance and increasing the breakdown voltage in the industry is effectively overcome.

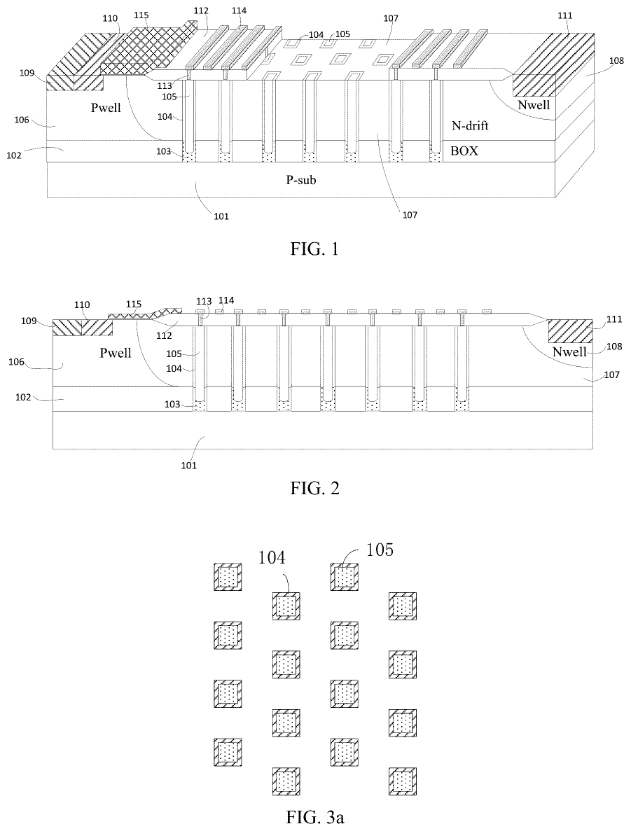

FIG. 1 is a perspective view of a SOI transverse device according to an embodiment, and FIG. 2 is a schematic cross-sectional view of the SOI transverse device shown in FIG. 1. In the embodiments shown in FIGS. 1 and 2, the SOI transverse device is a silicon-on-insulator laterally diffused metal-oxide-semiconductor field-effect transistor (SOI LDMOSFET), including a substrate 101, a buried dielectric layer 102, a drift region 107, a vertical conductive structure 105, a dielectric layer 104, and a low-K dielectric 103. The buried dielectric layer 102 is provided on the substrate 101. The drift region 107 is provided on the buried dielectric layer 102. Deep trenches are provided on the drift region 107 and the buried dielectric layer 102. The bottom of the deep trench is filled with the low-K dielectric 103 that replaces a material of the buried dielectric layer. The dielectric layer 104 is a sidewall of the deep trench above the low-K dielectric 103. The rest of the deep trench except for the low-K dielectric 103 and the dielectric layer 104 is filled with a conductive material to form the vertical conductive structure 105 extending downwards from the drift region 107 to the buried dielectric layer 102. The low-K dielectric 103 surrounds the bottom of the vertical conductive structure 105. A dielectric constant of the low-K dielectric 103 is less than a dielectric constant of the buried dielectric layer 102. In an embodiment of the present disclosure, the buried dielectric layer 102 is a buried oxide layer, which may be made of silicon oxide, such as silicon dioxide.

According to the above SOI transverse device, the vertical conductive structure 105, the dielectric layer 104, and the drift region 107 form a capacitor effect similar to the capacitor effect formed by a conductive material, a dielectric material and a semiconductor, which can assist in depletion of the drift region 107 and can also make the equipotential lines at the bottom of the drift region 107 be located at a structure below the vertical conductive structure 105. Since the low-K dielectric 103 replacing the material of the buried dielectric layer 102 is located at a portion with highest density of the equipotential lines, when the transverse device is in a reverse cutoff region, an electric field in the dielectric can be greatly enhanced, thereby increasing a breakdown voltage. In addition, due to the enhanced effect of the assisted depletion, the concentration in the drift region 107 can be flexibly adjusted, so that ON-resistance is reduced to some extent. Therefore, the above SOI transverse device can increase the breakdown voltage and reduce the ON-resistance of the device. In an embodiment of the present disclosure, the dielectric constant K of the low-K dielectric 103 is less than 3.9.

In the embodiments shown in FIGS. 1 and 2, the SOI transverse device further includes a source region 110, a drain region 111, a gate dielectric layer (not labeled in FIGS. 1 and 2), and a gate 115. The source region 110, the drain region 111, and the drift region 107 have a first conductivity type. The gate 115 is located above a region between the source region 110 and the drain region 111 and is located on the gate dielectric layer. The vertical conductive structure 105 is located between the gate 115 and the drain region 111. Each SOI LDMOS may be provided with a plurality of deep trenches each provided with the vertical conductive structure 105 and the low-K dielectric 103. In an embodiment of the present disclosure, the first conductivity type is N-type, and a second conductivity type is P-type. In other embodiments, the first conductivity type may be P-type, and the second conductivity type may be N-type. In an embodiment of the present disclosure, the source region 110 and the drain region 111 are N+ regions, and the drift region 107 is an N-region. In an embodiment of the present disclosure, the substrate 101 is a P-type silicon substrate.

In the embodiments shown in FIGS. 1 and 2, the SOI transverse device further includes a field oxide layer 112 provided on the drift region 107. The gate 115 extends from an edge of the source region 110 to the field oxide layer 112. In FIG. 1, a part of the field oxide layer is omitted to illustrate how the vertical conductive structure 105 is distributed on a surface of the drift region 107.

In the embodiments shown in FIGS. 1 and 2, the SOI transverse device further includes a substrate leading-out region 109. The substrate leading-out region 109 has the second conductivity type and is provided on a side of the source region 110 facing away from the gate 115. In an embodiment of the present disclosure, the substrate leading-out region 109 is a P+ region.

In the embodiments shown in FIGS. 1 and 2, the SOI transverse device further includes a first-conductivity-type well region 108 and a second-conductivity-type well region 106. The drain region 111 is located in the first-conductivity-type well region 108. The source region 110 and the substrate leading-out region 109 are located in the second-conductivity-type well region 106. All the vertical conductive structures 105 are located between the first-conductivity-type well region 108 and the second-conductivity-type well region 106. The second-conductivity-type well region 106 is a region where an inversion channel is formed, which directly affects a gate threshold voltage and also affects the depletion of the drift region. The first-conductivity-type well region 108 is a buffer layer in the drift region at a drain end of the SOI transverse device, which can increase an ON-breakdown-voltage of the device during forward operation.

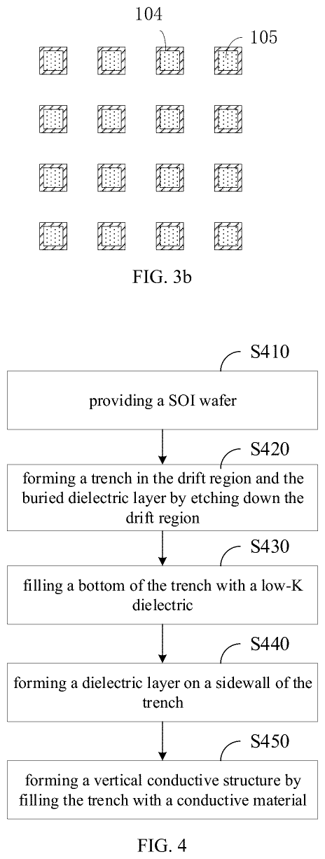

In an embodiment of the present disclosure, the drift region 107 is provided with at least one column of vertical conductive structures 105, each column includes at least two vertical conductive structures 105 spaced apart, and an angle between a column direction and a length direction of a conductive channel is greater than 0 degrees on a horizontal plane. The SOI transverse device further includes at least one conductive equipotential structure, and each conductive equipotential structure is electrically connected to one column of vertical conductive structures 105. Referring to FIG. 1, in this embodiment, a plurality of vertical conductive structures 105 are arranged in the drift region 107 to form an array structure. It may be understood that, in order to leave enough movement paths for carriers in the drift region 107, the vertical conductive structures 105 are not connected into one piece, but arranged in an array. FIGS. 3a and 3b are respectively schematic views of distribution of vertical conductive structures 105 on a cross section of the drift region 107 in two embodiments.

In the embodiments shown in FIGS. 1 and 2, the conductive equipotential structure is a plurality of conductive equipotential strips 114 provided on the field oxide layer 112. Each conductive equipotential strip 114 extends in a width direction of the conductive channel. Each conductive equipotential strip 114 extends downwards through the field oxide layer 112 by means of the conductive material 113 and is electrically connected to at least two vertical conductive structures 105 below it. As described above, in order to leave enough movement paths for carriers in the drift region 107, the vertical conductive structures 105 are not connected into one piece. Therefore, each conductive equipotential strip 114 and several conductive materials 113 electrically connect several vertical conductive structures 105 to each other to form an equipotential body and form an equipotential surface. The equipotential lines are concentrated at the bottom of the deep trench. In an embodiment of the present disclosure, the conductive equipotential strip 114 may be made of metal or alloy, and the conductive material 113 may also be metal or alloy. In an embodiment of the present disclosure, the conductive equipotential strip 114 may have a straight strip structure. In other embodiments of the present disclosure, the conductive equipotential strip 114 may alternatively have a curved strip structure or a bent strip structure.

In an embodiment of the present disclosure, the vertical conductive structure 105 is made of polysilicon. It is easy to fill the deep trench with a polysilicon material, which is relatively stable. Moreover, the polysilicon material may obtain a desired resistance value directly by impurity implantation or in-situ doping (that is, it is easy to adjust the resistance of the vertical conductive structure 105). In other embodiments, the vertical conductive structure 105 may alternatively be made of other conductive materials known in the art.

In an embodiment of the present disclosure, the low-K dielectric 103 is made of silicon oxyfluoride (SiOF). In other embodiments, the low-K dielectric 103 may alternatively be other low-K dielectrics known in the art.

In an embodiment of the present disclosure, the dielectric layer 104 is made of silicon oxide, such as silicon dioxide.

In an embodiment of the present disclosure, the gate dielectric layer is made of silicon oxide, such as silicon dioxide, and the gate 115 is made of polysilicon.

In an embodiment of the present disclosure, the bottom of the low-K dielectric 103 is in direct contact with the substrate 101.

In an embodiment of the present disclosure, the top of the low-K dielectric 103 is flush with the top of the buried dielectric layer 102.

In an embodiment of the present disclosure, the top of the low-K dielectric 103 is higher than the top of the buried dielectric layer 102.

In other embodiments of the present disclosure, the low-K dielectric 103 replaces only part of the material of the buried dielectric layer 102 at the bottom of the deep trench.

The present disclosure correspondingly provides a manufacturing method for a SOI transverse device, which may be used to manufacture the SOI transverse device according to any one of the above embodiments. FIG. 4 is a flowchart of a manufacturing method for a SOI transverse device according to an embodiment, including the following steps.

At S410, a SOI wafer is provided.

The SOI wafer is provided, with a buried dielectric layer formed on a substrate and a drift region formed on the buried dielectric layer.

In an embodiment of the present disclosure, the drift region has a first conductivity type, and the substrate has a second conductivity type. In an embodiment of the present disclosure, the first conductivity type is N-type, and the second conductivity type is P-type. Correspondingly, the substrate is a P-type silicon substrate, and the drift region is an N-drift region. In other embodiments, the first conductivity type may be P-type, and the second conductivity type may be N-type. In an embodiment of the present disclosure, the drift region is realized by well drive-in at high-temperature after implantation, which requires a certain doping concentration to ensure a current path.

In an embodiment of the present disclosure, the buried dielectric layer is a buried oxide layer, which may be made of silicon oxide, such as silicon dioxide.

At S420, a trench in the drift region and the buried dielectric layer are formed by performing an etching to etch down into the drift region.

The drift region is photoetched and etched. The etching is performed to etch through the drift region, and then continuously etching down into the buried dielectric layer, thereby forming a deep trench in the drift region and the buried dielectric layer.

In an embodiment of the present disclosure, the etching in step S420 is to etch through the buried dielectric layer to the substrate. In other embodiments of the present disclosure, the etching in step S420 is not to etch through the buried dielectric layer. That is, a certain thickness of the buried dielectric layer remains at the bottom of the deep trench.

At S430, the bottom of the trench is filled with a low-K dielectric.

It may be understood that a dielectric constant K of the low-K dielectric is at least less than a dielectric constant K of the material of the buried dielectric layer. In an embodiment of the present disclosure, the dielectric constant K of the low-K dielectric is less than 3.9.

In an embodiment of the present disclosure, after the bottom of the deep trench is filled with the low-K dielectric, the low-K dielectric is etched back, so that a recess is formed on the low-K dielectric at the bottom of the deep trench, and subsequently, the recess can be filled with the conductive material that fills the deep trench.

In an embodiment of the present disclosure, a filling thickness of the low-K dielectric is the same as a thickness of the buried dielectric layer, and then the low-K dielectric is etched back so that the top of the low-K dielectric is flush with the top of the buried dielectric layer. In another embodiment of the present disclosure, the filling thickness of the low-K dielectric may alternatively be greater than the thickness of the buried dielectric layer.

At S440, a dielectric layer is formed on a sidewall of the trench.

In an embodiment of the present disclosure, a silicon oxide layer as a dielectric layer is formed on the sidewall of the deep trench by thermal oxidation. In other embodiments, the dielectric layer may alternatively be formed on the sidewall of the deep trench through other processes known in the art.

At S450, the trench is filled with a conductive material to form a vertical conductive structure.

In an embodiment of the present disclosure, the conductive material in the deep trench is polysilicon. The bottom of the vertical conductive structure is surrounded by the low-K dielectric. Polysilicon with certain doping concentration may be deposited into the deep trench through a deposition process. In an embodiment of the present disclosure, the doping concentration of polysilicon may be adjusted through a doping process such as in-situ doping, thereby adjusting a resistance value of polysilicon.

In an embodiment of the present disclosure, a plurality of deep trenches are formed in the drift region (correspondingly, a plurality of vertical conductive structures are formed), and the vertical conductive structures are arranged in the drift region to form an array structure.

According to the above manufacturing method for a SOI transverse device, the vertical conductive structure, the dielectric layer (on the sidewall of the deep trench), and the drift region form a capacitor effect similar to the capacitor effect formed by a conductive material, a dielectric material, and a semiconductor, which can assist in depletion of the drift region and can also make equipotential lines at the bottom of the drift region be located at a structure below the vertical conductive structure. Since the low-K dielectric is located at a portion with highest density of the equipotential lines, when the transverse device is in a reverse cutoff region, an electric field in the dielectric can be greatly enhanced, thereby increasing a breakdown voltage. In addition, due to the enhanced effect of the assisted depletion, the concentration in the drift region can be flexibly adjusted, so that ON-resistance is reduced to some extent. Therefore, the above SOI transverse device can increase the breakdown voltage and can also reduce the ON-resistance of the device.

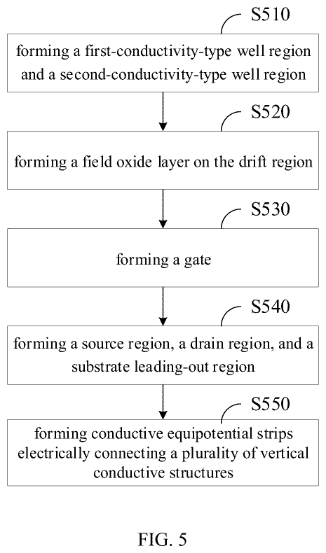

Referring to FIG. 5, in an embodiment of the present disclosure, the manufacturing method for a SOI transverse device further includes, after step S450, the following steps.

At S510, a first-conductivity-type well region and a second-conductivity-type well region are formed.

In an embodiment of the present disclosure, the transverse device is a SOI LDMOSFET. The first-conductivity-type well region and the second-conductivity-type well region may be formed by photoetching and ion implantation processes. The first-conductivity-type well region is formed on one side of the drain, and the second-conductivity-type well region is formed on one side of the source. The vertical conductive structures are located between the first-conductivity-type well region and the second-conductivity-type well region. The second-conductivity-type well region is a region where an inversion channel is formed, which directly affects a gate threshold voltage and also affects the depletion of the drift region. The first-conductivity-type well region is a buffer layer in the drift region at a drain end of the SOI transverse device, which can increase an ON-breakdown-voltage of the device during forward operation.

At S520, a field oxide layer is formed on the drift region.

In an embodiment of the present disclosure, an oxide layer may be formed outside an active region and above the drift region, as a field oxide layer, through a deposition process and patterning.

At S530, a gate is formed.

A gate dielectric layer is formed first, and then the gate is formed on the gate dielectric layer. The gate extends from an edge of the field oxide layer to the field oxide layer and then extends to the second-conductivity-type well region. In an embodiment of the present disclosure, the gate dielectric layer is made of silicon oxide, such as silicon dioxide, and the gate is made of polysilicon.

At S540, a source region, a drain region, and a substrate leading-out region are formed.

Through an ion implantation process, the source region and the substrate leading-out region are formed in the second-conductivity-type well region, and the drain region is formed in the first-conductivity-type well region. In an embodiment of the present disclosure, the source region and drain region are N+ doped regions, and the substrate leading-out region is a P+ doped region.

At S550, conductive equipotential strips electrically connecting several vertical conductive structures are formed.

In an embodiment of the present disclosure, an interlayer dielectric layer (ILD) is firstly formed on a surface of the wafer obtained in step S540. Then, through an etching process, a structure required to be led out to a surface of the device is etched to form a contact hole extending through the ILD. Finally, conductive equipotential strips and metal electrodes for gate, drain, and source are formed. In an embodiment of the present disclosure, each conductive equipotential strip extends downwards through the field oxide layer by means of the conductive material and is electrically connected to at least two vertical conductive structures below the field oxide layer. That is, the vertical conductive structures are led out to the surface via the conductive material, and are connected to each other through the conductive equipotential strips. In an embodiment of the present disclosure, the conductive equipotential strip may be made of metal or alloy, and the conductive material may also be metal or alloy.

It should be understood that, although the steps in the flowcharts of the present disclosure are shown in sequence as indicated by the arrows, these steps are not necessarily performed in the order indicated by the arrows. Unless otherwise clearly specified herein, these steps are performed without any strict sequence limitation, and may be performed in other orders. In addition, at least some steps in the flowcharts of the present disclosure may include a plurality of steps or a plurality of stages, and such steps or stages are not necessarily performed at a same moment, and may be performed at different moments. These steps or stages are not necessarily performed in sequence, and the steps or stages and at least some of other steps or sub-steps or sub-stages of other steps may be performed in turn or alternately.

In the description of the specification, reference terms such as “some embodiments”, “other embodiments”, and “ideal embodiments” mean that a particular feature, structure, material, or characteristic described in connection with the embodiment or example is included in at least one embodiment or example of the present disclosure. In the specification, illustrative descriptions of the above terms do not necessarily refer to a same embodiment or example.

The technical features in the above embodiments may be randomly combined. For concise description, not all possible combinations of the technical features in the above embodiments are described. However, all the combinations of the technical features are to be considered as falling within the scope of this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variants and improvements without departing from the conception of the present disclosure, and these all fall within the protection scope of the present disclosure. Therefore, the patent protection scope of the present disclosure should be subject to the appended claims.

1. A silicon-on-insulator (SOI) transverse device, comprising:
a substrate;
a buried dielectric layer provided on the substrate;
a drift region provided on the buried dielectric layer;
a vertical conductive structure extending downwards from the drift region to the buried dielectric layer;
a low-K dielectric provided in the buried dielectric layer and surrounding a bottom of the vertical conductive structure, a dielectric constant of the low-K dielectric being less than a dielectric constant of the buried dielectric layer; and
a dielectric layer provided on a side surface of the vertical conductive structure and located between the vertical conductive structure and the drift region and above the low-K dielectric.

2. The SOI transverse device according to claim 1, wherein the transverse device is a laterally diffused metal-oxide-semiconductor field-effect transistor (LDMOSFET), and the transverse device further includes:
a source region;
a drain region; and
a gate provided above a region between the source region and the drain region;
wherein the vertical conductive structure is located between the gate and the drain region; and the source region, the drain region, and the drift region have a first conductivity type.

3. The SOI transverse device according to claim 2, further comprising:
a field oxide layer provided on the drift region; and
a substrate leading-out region having a second conductivity type and provided on a side of the source region facing away from the gate;
wherein the gate extends from an edge of the source region to the field oxide layer.

4. The SOI transverse device according to claim 3, further comprising a first-conductivity-type well region and a second-conductivity-type well region;
wherein the drain region is located in the first-conductivity-type well region; the source region and the substrate leading-out region are located in the second-conductivity-type well region; and the vertical conductive structure is located between the first-conductivity-type well region and the second-conductivity-type well region.

5. The SOI transverse device according to claim 1, wherein the drift region is provided with at least one column of vertical conductive structures, each column including at least two vertical conductive structures spaced apart, and an angle between a column direction and a length direction of a conductive channel is greater than 0 degrees on a horizontal plane; and wherein the SOI transverse device further includes at least one conductive equipotential structure, each conductive equipotential structure being electrically connected to one column of vertical conductive structures.

6. The SOI transverse device according to claim 3, wherein the drift region is provided with at least one column of vertical conductive structures, each column including at least two vertical conductive structures spaced apart, and a column direction is a width direction of a conductive channel; and wherein the SOI transverse device further includes at least one conductive equipotential strip provided on the field oxide layer, each conductive equipotential strip extending downwards through the field oxide layer by means of a conductive material and being electrically connected to one column of vertical conductive structures.

7. The SOI transverse device according to claim 1, wherein the vertical conductive structure is made of a material including polysilicon.

8. The SOI transverse device according to claim 1, wherein the low-K dielectric is made of a material including silicon oxyfluoride.

9. The SOI transverse device according to claim 1, wherein a bottom of the low-K dielectric is in direct contact with the substrate.

10. The SOI transverse device according to claim 1, wherein a top of the low-K dielectric is flush with a top of the buried dielectric layer or higher than the top of the buried dielectric layer.

11. A manufacturing method for a SOI transverse device, comprising:
providing a SOI wafer, the SOI wafer including a substrate, a buried dielectric layer on the substrate, and a drift region on the buried dielectric layer;
forming a trench in the drift region and the buried dielectric layer by etching down the drift region, etching through the drift region, and then continuously etching the buried dielectric layer;
filling a bottom of the trench with a low-K dielectric;
forming a dielectric layer on a sidewall of the trench; and
forming a vertical conductive structure by filling the trench having the dielectric layer formed on the sidewall with a conductive material;
wherein a dielectric constant of the low-K dielectric is less than a dielectric constant of the buried dielectric layer.

12. The manufacturing method according to claim 11, wherein the etching the buried dielectric layer includes etching through the buried dielectric layer to the substrate.

13. The manufacturing method f according to claim 11, further comprising, subsequent to the filling the bottom of the trench with the low-K dielectric and prior to the forming the dielectric layer on the sidewall of the trench: etching back the low-K dielectric.

14. The manufacturing method according to claim 11, wherein the forming the vertical conductive structure by filling the trench having the dielectric layer formed on the sidewall with the conductive material further includes causing the low-K dielectric to surround a bottom of the vertical conductive structure.

15. The manufacturing method according to claim 11, further comprising, subsequent to the forming the vertical conductive structure by filling the trench having the dielectric layer formed on the sidewall with the conductive material:
forming a first-conductivity-type well region and a second-conductivity-type well region;
forming a field oxide layer on the drift region;
forming a gate;
forming a source region and a substrate leading-out region in the second-conductivity-type well region and forming a drain region in the first-conductivity-type well region; and
forming conductive equipotential strips electrically connecting a plurality of vertical conductive structures.
